(19) United States
(12) Patent Application Publication
(10) Pub. No.: US 2011/0000232 A1
(43) Pub. Date: Jan. 6, 2011

(54) LOAD LOCK APPARATUS AND SUBSTRATE COOLING METHOD

(75) Inventor: Ryoji Yamazaki, Yamanashi (JP)

Correspondence Address: CANTOR COLBURN LLP, 20 Church Street, 22nd Floor, Hartford, CT, 06103, US

(73) Assignee: TOKYO ELECTRON LIMITED, Tokyo (JP)

(21) Appl. No.: 12/919,674

(22) PCT Filed: Feb. 25, 2009
(86) PCT No.: PCT/JP2009/053414

§ 371 Date: Aug. 26, 2010

(30) Foreign Application Priority Data
Feb. 27, 2008 (JP) 2008-046405

(51) Int. Cl. F25D 25/00; H01L 21/677

(52) U.S. Cl. 62/63; 414/217

(57) ABSTRACT

Disclosed are load lock apparatuses configured to cool a substrate efficiently. The load lock apparatus includes a container configured to change the pressure between an atmospheric pressure and a pressure corresponding to a transfer chamber which is in a vacuum state, a pressure adjusting mechanism configured to adjust the pressure in container to the pressure corresponding to transfer chamber and an atmospheric pressure. The load lock apparatus further includes an upper cooling plate and a lower cooling plate provided opposed to each other inside container and each configured to cool the wafer at a position adjacent to the wafer or in touch with the wafer, and a wafer elevating pin and a driving mechanism that transfer the wafer to the cooling position of lower cooling plate. The load lock apparatus also includes a wafer supporting member and driving mechanism that transfer the wafer W to the cooling position of upper cooling plate.

### TECHNICAL FIELD

The present invention relates to a load lock apparatus used for a vacuum processing apparatus which performs a vacuum process for a substrate to-be-processed such as a semiconductor wafer, and a substrate cooling method in the load lock apparatus.

### BACKGROUND

In semiconductor device manufacturing processes, a vacuum process such as a film deposition process or an etching process in a vacuum state has been frequently used for a semiconductor wafer (hereinafter “wafer”) which is a substrate to-be-processed. Recently, in an effort to improve the vacuum processing efficiency and prevent the contamination or the oxidization, a multi-chamber vacuum processing system of a cluster-tool type has attracted an attention. The multi-chamber vacuum processing system of a cluster-tool type includes a plurality of vacuum processing units each connected to a transfer chamber maintained with a vacuum state, and allows a wafer to be transferred to each vacuum processing unit by a transfer apparatus provided in the transfer chamber. See, for example, Japanese Patent Laid-open Publication No. 2000-208589.

The multi-chamber processing systems is provided with a load lock chamber between a transfer chamber maintained with a vacuum state and a wafer cassette placed in an atmospheric state for transferring the wafer through the load lock chamber.

However, when the multi-chamber processing system is used for a high-temperature processing such as a film deposition process, the wafers are brought out from the vacuum processing unit and transferred to the load lock chamber with a high-temperature state (e.g., 500° C.). However, the wafers are oxidized when exposed to the air with the high-temperature. Also, the wafer receiving vessels normally made from resin material shall be melted, when the wafers are received at the receiving vessels in the high-temperature state.

In order to avoid the problems described above, a cooling plate equipped with a cooling apparatus for cooling the wafers is provided in the load lock chamber, and the wafer cooling method is performed by making the wafers to move adjacent to or in touch with the cooling plate while the load lock chamber is returned from the vacuum state to an atmospheric state.

At this time, if the wafer is cooled rapidly, the wafer may be deflected due to the difference of the thermal expansion (contraction) in both sides of the wafer and the cooling efficiency may be decreased. Accordingly, the wafer needs to be cooled in a cooling speed that the wafer is not deflected. As a result, it takes a long time to cool the wafer, and the wafer cooling time at the load lock chamber limits the processing speed of the entire processing system. That is, the number of processed wafers is limited by the cooling time at the load lock chamber and the throughput is decreased.

### SUMMARY

The present invention provides a load lock apparatus which can cool the substrate efficiently and improve the throughput of the substrate processing. The present invention also provides a substrate cooling method in the load lock apparatus.

According to a first embodiment of the present invention, there is provided a load lock apparatus for transferring a substrate from an atmospheric environment to a vacuum chamber maintained in a vacuum state, and for transferring a high-temperature substrate from the vacuum chamber to the atmospheric environment. The load lock apparatus includes a container configured to change pressure thereof between an atmospheric pressure and a pressure corresponding to the vacuum chamber, and a pressure adjusting mechanism configured to adjust the pressure in the container to the pressure corresponding to the vacuum chamber when the container is in communication with the vacuum chamber, and to adjust the pressure in the container to the atmospheric pressure when the container is in communication with a space of the atmosphere. The load lock apparatus also includes a first cooling member and a second cooling member provided opposed to each other inside the container and configured to cool the substrate at a place adjacent to the substrate or in touch with the substrate, a first transfer mechanism configured to receive the substrate transferred inside the container and to transfer the substrate to a position adjacent to the first cooling member or in touch with the first cooling member, and a second transfer mechanism configured to receive the substrate transferred inside the container and to transfer the substrate to a position adjacent to the second cooling member or in touch with the second cooling member.

In the first embodiment described above, the first transfer mechanism may transfer the substrate between a transfer position where the substrate is delivered to and from an outside transfer arm and a cooling position adjacent to the first cooling member or in touch with the first cooling member, and the second transfer mechanism may transfer the substrate between a transfer position where the substrate is delivered to and from an outside transfer arm and a cooling position adjacent to the second cooling member or in touch with the second cooling member.

The load lock apparatus described above may further include a control unit configured to control the first and the second transfer mechanisms so that while cooling the substrate by making the substrate to touch or to move adjacent to any one of the first and the second cooling members by any one of the first and the second transfer mechanisms, the substrate is transferred to the other one of the first and the second cooling members by the other one of the first and the second transfer mechanisms.

Each of the first and the second transfer mechanisms may include a substrate supporting member to support the substrate and a driving mechanism to drive the substrate supporting member.

The first cooling member may be provided at the lower part of the container to cool the substrate from a downside, and the second cooling member may be provided at an upper part of the container to cool the substrate from an upside. In this case, the first transfer mechanism may include a support pin provided on the first cooling member to be able to protrude and retract, and a driving mechanism configured to elevate the support pin. And the second transfer mechanism may include a substrate support member configured to support the substrate and provided in contact with or detachable from the second cooling member, and a driving mechanism to elevate the substrate support member.

Each of the first and the second transfer mechanisms may include either an independent drive mechanism, or a common drive mechanism.

According to a second embodiment of the present invention, there is provided a substrate cooling method for a load lock apparatus for transferring a substrate from an atmospheric environment to a vacuum chamber maintained in a vacuum state and for transferring a high-temperature substrate from the vacuum chamber to the atmospheric environment. The load lock apparatus includes a container configured to change pressure between an atmospheric pressure and a pressure corresponding to the vacuum chamber, and a pressure adjusting mechanism configured to adjust the pressure in the container to the pressure corresponding to the vacuum chamber when the container is in communication with the vacuum chamber and to adjust the pressure in the container to the atmospheric pressure when the container is in communication with the vacuum chamber. The load lock apparatus also includes a first and a second cooling members provided opposed to each other inside the container and configured to cool the substrate at a place adjacent to the substrate or in touch with the substrate, a first transfer mechanism configured to receive the substrate transferred inside the container and to transfer the substrate to a position adjacent to the first cooling member or in touch with the cooling member, and a second transfer mechanism configured to receive the substrate transferred inside the container and to transfer the substrate to a position adjacent to the second cooling member or in touch with the second cooling member. The substrate cooling method includes cooling the substrate by moving the substrate into a place adjacent to or touching any one of the first and the second cooling members by any one of the first and the second transfer mechanisms, and transferring the substrate to the other one of the first and the second cooling members by the other one of the first and the second transfer mechanisms while cooling the substrate.

According to the present invention, the first and second cooling members are provided in the container to be opposed each other and each of the cooling members can perform a cooling process of the substrate independently. As a result, the substrate can be cooled with a high efficiency, and the processing speed of the entire system can be prevented from being limited by the substrate cooling time in the load lock apparatus. For this reason, the number of processing of the substrates is not limited by the cooling time at the load lock apparatus, and the substrate processing can be done with a high throughput.

Also, while a substrate is being cooled in one of the cooling members, another substrate may be transferred to the other cooling member allowing each of the two cooling members can perform the substrate transfer operation and the cooling operation with an independent sequence. Accordingly, the flexibility of the cooling operation is increased.

### BRIEF DESCRIPTION OF THE DRAWINGS

FIG. 1 is a plan view illustrating a multi-chamber type vacuum processing system equipped with a load lock apparatus, according to an exemplary embodiment of the present invention.

FIG. 2 is a vertical cross-sectional view of the load lock apparatus, according to an exemplary embodiment of the present invention.

FIG. 3 is a horizontal cross-sectional view of the load lock apparatus, according to an exemplary embodiment of the present invention.

FIG. 4 is a schematic view illustrating the configuration where a wafer is being transferred to a lower cooling plate in the load lock apparatus, according to an exemplary embodiment of the present invention.

FIG. 5 is a schematic view illustrating the configuration where a wafer is being transferred to an upper cooling plate while another wafer is being cooled at a lower cooling plate in the load lock apparatus, according to an exemplary embodiment of the present invention.

FIG. 6 is a schematic view illustrating the configuration where a wafer is being cooled at both of the lower and the upper cooling plates in the load lock apparatus, according to an exemplary embodiment of the present invention.

FIG. 7 is a schematic view illustrating the configuration where a wafer is being transferred to an upper cooling plate while another wafer is being cooled at a lower cooling plate in the load lock apparatus, according to an exemplary embodiment of the present invention.

FIG. 8 is a vertical cross-sectional view illustrating a load lock apparatus according to another exemplary embodiment of the present invention.

FIG. 9a is a schematic view illustrating the operation of the load lock chamber shown in FIG. 8.

FIG. 9b is a schematic view illustrating the operation of the load lock chamber in FIG. 8.

### DETAILED DESCRIPTION OF EMBODIMENTS

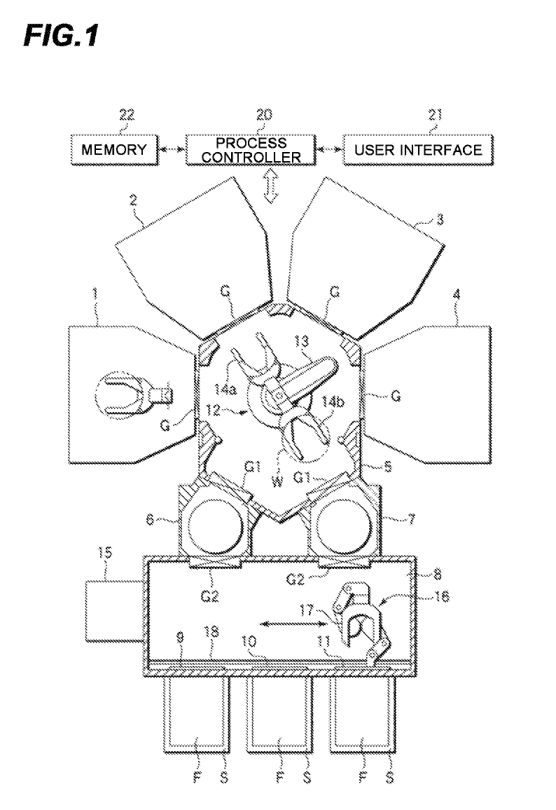

Hereinafter, exemplary embodiments of the present invention will be described with reference to the drawings. FIG. 1 is a horizontal cross-sectional view illustrating the schematic structure of a multi-chamber type vacuum processing system equipped with a load lock apparatus, according to an exemplary embodiment of the present invention.

The vacuum processing system is provided with, for example, four vacuum processing units 1, 2, 3, 4 each performing a high-temperature processing such as a film deposition processing, and each of the four vacuum processing units 1, 2, 3, 4 is provided correspondingly on each of the four sides of a transfer chamber 5 which forms a hexagonal shape. Also, each of load lock apparatuses 6, 7 is provided on each of the other two sides of transfer chamber 5, according to the exemplary embodiment. An atmospheric transfer chamber 8 is provided on the opposite side to transfer chamber 5 with respect to load lock apparatuses 6, 7, and ports 9, 10, 11 are provided on the opposite side to load lock apparatuses 6, 7 in atmospheric transfer chamber 8. Ports 9, 10, 11 are configured to receive three receiving vessels that accommodate wafers as substrates to-be-processed. Each of vacuum processing units 1, 2, 3, 4 is adapted to perform a predetermined vacuum process such as an etching or a film deposition processes by placing the substrates on the substrate mounting table provided inside vacuum processing units 1, 2, 3, 4.

Each of vacuum processing units 1, 2, 3, 4 as shown in FIG. 1, is connected to each side of transfer chamber 5 via gate valves G. Accordingly, each of vacuum processing units 1, 2, 3, 4 is in communication with transfer chamber 5 by opening a corresponding gate valve G, and blocked from transfer chamber 5 by closing the corresponding gate valve G. Also, each of load lock apparatuses 6, 7 is connected to each of the other sides of transfer chamber 5 via a first gate valve G1, and is connected to atmospheric transfer chamber 8 via a second gate valve G2. Also, each of load lock apparatuses 6, 7 is in communication with transfer chamber 5 by opening the first gate valve G1 and is blocked from transfer chamber 5 by closing the first gate valve G1. Also, each of load lock apparatuses 6, 7 is in communication with atmospheric transfer chamber 8 by opening the second gate valve G2 and blocked from atmospheric transfer chamber 8 by closing the second gate valve G2.

A transfer apparatus 12 is provided in transfer chamber 5 which carries-in and out the wafers W for vacuum processing units 1, 2, 3, 4 and load lock apparatuses 6, 7. Transfer apparatus 12 is provided approximately in the center of transfer chamber 5 with two support arms 14a, 14b that support the wafers W at the front-end of rotation-extension portion 13 which is configured to be rotatable and extendable. Two support arms 14a, 14b are installed at rotation-extension portion 13 opposing each other. The inside of transfer chamber 5 is maintained with a predetermined vacuum level.

A shutter (not shown) is provided on each of ports 9, 10, 11 which accommodate a FOUP (Front Opening Unified Pod) which is a receiving vessel for wafers in atmospheric transfer chamber 8. The FOUP F is mounted directly to stages S of ports 9, 10, 11 either with wafers are being accommodated or not accommodated, and in communication with atmospheric transfer chamber 8 when the FOUP F is mounted and the shutter is opened so that the outside air is prevented from being entered. Also, alignment chamber 15 is provided on the side of atmospheric transfer chamber 8, and the alignment of wafer W is carried out thereon.

A transfer apparatus 16 is provided in atmospheric transfer chamber 8 for carrying-in and carrying-out the wafer W between the FOUP F and load lock apparatuses 6, 7. Transfer apparatus 16 has a multi-joint arm structure, and is moveable on a rail 18 along the arrangement direction of the FOUP F. Transfer apparatus 16 transfers the wafer W by placing the wafer W on a support arm 17 of the front-end of transfer apparatus 16.

The vacuum processing system is provided with a process controller 20 formed with a micro-processor (computer) which controls each component, and each component is adapted to be connected to process controller 20 for the control. Also, a user interface 21 is connected to processor controller 20. User interface 21 is formed with a key board through which an operator inputs operation commands for managing processing apparatuses, and a display which displays the operation of a processing apparatus and so on.

Also, a memory unit 22 is connected to process controller 20. Memory unit 22 stores a control program to realize the control of the various processing performed at the processing apparatus and a recipe which is a program for performing the process for each component of the processing apparatus based on processing conditions. The recipe is stored at a storage medium of memory unit 22. The storage medium may be a fixed type such as the hard disk. The storage medium may also be a portable type such as CD-ROM, DVD, and flash memory. Alternatively, the recipe may be transmitted through a different apparatus such as a dedicated line.

Also, if needed, an arbitrary recipe may be called out from memory unit 22 by the command from user interface 21 and executed at process controller 20 so that a desired process may be performed at the processing apparatus under the control of process controller 20.

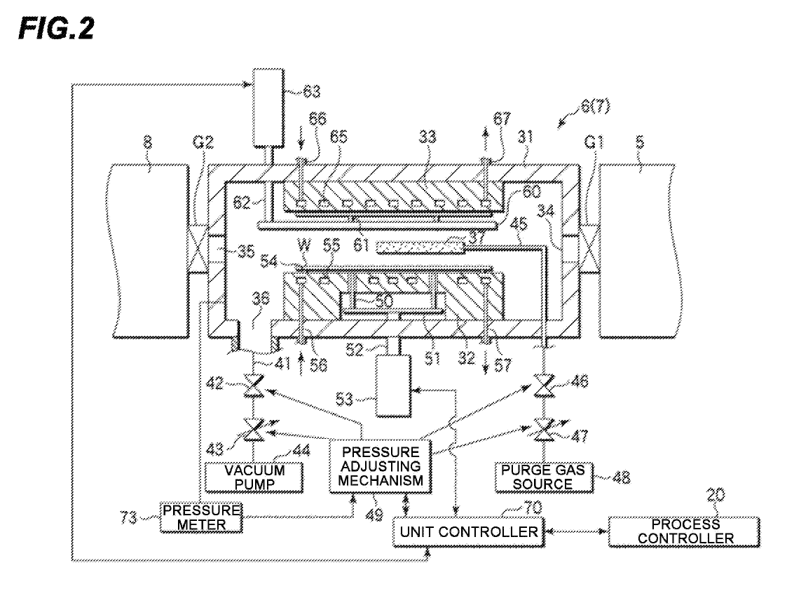

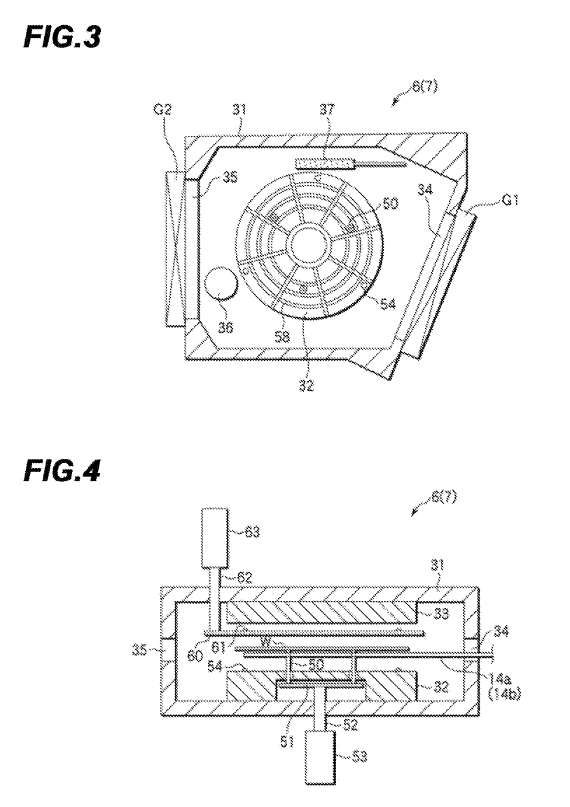

Next, load lock apparatuses 6, 7 according to the exemplary embodiment are described in detail. FIG. 2 is a vertical cross-sectional view of the load lock apparatus, according to the exemplary embodiment, and FIG. 3 is a horizontal cross-sectional view thereof. Each of load lock apparatuses 6, 7 has a container 31, and a lower cooling plate 32 and an upper cooling plate 33 are provided in the lower side and the upper side of container 31 to cool the wafer W from a place adjacent to the wafer W.

A side wall of container 31 is provided with an opening 34 which can communicate with transfer chamber 5 maintained with a vacuum state, and an opening 35 is provided at the other side wall opposite to the side wall of container 31 which can communicate with atmospheric transfer chamber 8 maintained at an atmospheric pressure. Also, each of openings 34, 35 is allowed to be opened or closed by the first and second gate valves G1, G2, respectively.

The bottom portion of container 31 is provided with an exhaustion port 36 to vacuum exhaust the inside of container 31. An exhaustion pipe 41 is connected to exhaustion port 36, and is provided with an opening/closing valve 42, an exhaustion speed adjusting valve 43 and a vacuum pump 44.

Also, a purge gas introducing member 37 made from a porous ceramic is provided near the side wall of the inside of container 31 at the middle-height thereof for introducing the purge gas into container 31. Purge gas introducing member 37 has a filtering function and a function of introducing the purge gas into container 31 gradually. A purge gas supplying pipe 45 is connected to purge gas introducing member 37. Purge gas introducing pipe 45 is extended from a purge gas source 48, and is provided with an opening/closing valve 46 and a flow control valve 47 on the road of purge gas introducing pipe 45.

And, when the wafer W is transferred between load lock apparatuses 6, 7 and transfer chamber 5 which is a vacuum side, opening/closing valve 46 is closed, opening/closing valve 42 is opened, and the inside of container 31 is exhausted with a predetermined speed through exhaustion tube 41 by controlling exhaust speed adjusting valve 43 of vacuum pump 44. The pressure in container 31 is then set to a pressure corresponding to the pressure of transfer chamber 5, and container 31 and transfer chamber 5 are in communication with each other by opening the first gate valve G1. Also, when the wafer W is transferred between load lock apparatuses 6, 7 and atmospheric transfer chamber 8 which is an atmospheric side, opening/closing valve 42 is closed, opening/closing valve 46 is opened, and the purge gas such as nitrogen gas is introduced from purge gas source 48 to container 31 in a predetermined flow rate through purge gas introducing pipe 45 by controlling flow control valve 47. The pressure therein is set to near the atmospheric pressure, and then container 31 and atmospheric transfer chamber 8 are in communication with each other by opening the second gate valve G2.

The pressure in container 31 is adjusted between an atmospheric pressure and a predetermined vacuum state by a pressure adjusting mechanism 49. Pressure adjusting mechanism 49 adjusts the pressure in container 31 by controlling opening/closing valve 42, exhaust speed adjusting valve 43, flow control valve 47 and opening/closing valve 46, based on the pressure in container 31 measured by a pressure meter 73. Pressure adjusting mechanism 49 is controlled by a unit controller 70 as described below.

Lower cooling plate 32 is provided with three wafer elevating pins 50 (only two are illustrated in FIG. 2) for wafer transfer in such a way that three wafer elevating pins 50 are able to protrude and retract on the (upper) surface of lower cooling plate 32 and are fixed to a support plate 51. Also, wafer elevating pin 50 is elevated via support plate 51 by elevating a rod 52 with a driving mechanism 53 such as an air cylinder. Wafer elevating pin 50 takes two positions, that is, of the transfer position and the cooling position. In the transfer position, wafer elevating pin 50 is protruded from the (upper) surface and transfers the wafer W from and to support arm 14a or 14b or a support arm 17, when support arm 14a or 14b of transfer apparatus 12 in transfer chamber 5 or support arm 17 of transfer apparatus 16 in atmospheric transfer chamber 8, is inserted into container 31. In the cooling position, wafer elevating pin 50 is retracted into lower cooling plate 32 and moves the wafer W adjacent to the (upper) surface of low cooling plate 32. Three wafer support pins 54 (only two are illustrated in FIG. 2) are mounted on the (upper) surface of low cooling plate 32, and the wafer W in the cooling position is slightly detached from lower cooling plate 32 by wafer support pins 54. Also, grooves 58 are formed concentrically and radially on the surface of low cooling plate 32.

A cooling medium flow passage 55 is formed in lower cooling plate 32, and a cooling medium inlet 56 and a cooling medium outlet 57 are connected to cooling medium flow passage 55 so that the cooling medium such as the cooling water flows from a cooling medium supply (not shown) and the wafer W adjacent to lower cooling plate 32 is able to be cooled.

A wafer support arm 60, which is able to be elevated, is provided on the upper side of container 31. Three wafer support pins 61 (only two are illustrated in FIG. 2) are provided on the upper surface of wafer support arm 60. Wafer support arm 60 can be elevated by elevating a rod 62 by driving mechanism 63 such as an air cylinder. Wafer support arm 60 has two positions of the transfer position and the cooling position. The transfer position is a descending position where wafer support arm 60 transfers the wafer W from and to support arm 14a or 14b, or a support arm 17, when support arm 14a or 14b of transfer apparatus 12 in transfer chamber 5, or support arm 17 of transfer apparatus 16 in atmospheric transfer chamber 8 is inserted into container 31. The cooling position is an elevated position where wafer support arm 60 moves the wafer W adjacent to the (lower) surface of upper cooling plate 33. A stopper (not illustrated) is provided on rod 62 in order to prevent the wafer W from contacting with the (lower) surface of upper cooling plate 33. Also, grooves are formed concentrically and radially on the (lower) surface of upper cooling plate 33.

Though cooling medium flow passage 65 is formed in upper cooling plate 33, and cooling medium inlet 66 and cooling medium outlet 67 are connected to cooling medium flow passage 65, the cooling medium such as the cooling water flows from the cooling medium supply (not illustrated) so that the wafer W adjacent to upper cooling plate 33 can be cooled.

Unit controller 70 is for controlling load lock apparatuses 6, 7 and functions as a sub-controller of process controller 20. Unit controller 70 is adapted to control pressure adjusting mechanism 49, driving mechanisms 53, 63 and gate valves G1, G2, and so on.

Next, the operation of multi-chamber type vacuum processing system as described above is explained with regard to load lock apparatuses 6, 7 in the exemplary embodiment.

To begin with, wafer W is carried out from the FOUP F connected to atmospheric transfer chamber 8 by transfer apparatus 16 and carried into container 31 of load lock apparatuses 6 or 7. At this time, the inside of container 31 of load lock apparatus 6 becomes atmospheric, and then the wafer W is carried in with the second gate valve G2 opened.

Next, the inside of container 31 is vacuum exhausted until it reaches to the corresponding pressure of transfer chamber 5. The first gate valve G1 is opened, and the wafer W is received and carried out from the inside of container 31 by support arm 14a or 14b of transfer apparatus 12. The gate valve G of any one of vacuum processing unit is opened, and the wafer W is carried therein and vacuum processed for, for example, a film deposition at a high-temperature.

At the time when a vacuum processing is completed, the gate valve G is opened, the wafer W is carried out from the corresponding vacuum processing unit by support arm 14a or 14b of transfer apparatus 12, and the first gate valve G1 is opened to carry the wafer W to any one container 31 among load lock apparatuses 6, 7.

In this case, support arm 14a, 14b mounted with the wafer W is inserted into container 31, and the wafer W is received by elevating wafer elevating pin 50 to the transfer position, as shown in FIG. 4, for the first time. Next, the first gate valve G1 is closed, and purge gas, such as, for example, nitrogen gas is introduced as a heat transfer gas from purge gas source 48. As a result, the pressure in container 31 is raised to an appropriate value according to the kind of gas and the distance between upper cooling plate 33 and lower cooling plate 32. The wafer W is then moved down to the cooling position along with wafer elevating pin 50, and the wafer W begins to be cooled by lower cooling plate 32.

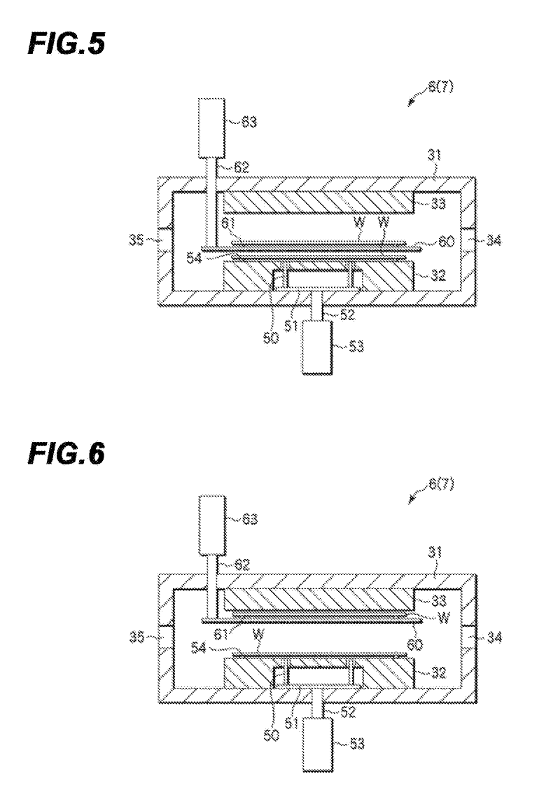

When a next wafer W needs to be cooled while cooling the first wafer W, the pressure in container 31 is adjusted, and the first gate valve G1 is opened. The wafer W is then carried into container 31 by support arm 14a or 14b, and received with a state where wafer support arm 60 is descended to the transfer position, as shown in FIG. 5. Then, the first gate valve G1 is closed, and the purge gas, such as, for example, nitrogen gas is introduced as a heat transfer gas from purge gas source 48. Thereafter, the same pressure adjustment is performed as described above, and the wafer W is elevated to the cooling position adjacent to the lower surface of upper cooling plate 33 by elevating wafer support arm 60 mounted with the wafer W thereon. The wafer W then begins to be cooled by upper cooling plate 33. As a result, two wafers W are cooled by lower cooling plate 32 and upper cooling plate 33, as shown in FIG. 6.

When the wafer W is carried out after the cooling of the first wafer W is completed, the pressure in container 31 becomes an atmospheric pressure by increasing the pressure of the purge gas, and the gate valve G2 is opened. The first wafer W is then carried out to atmospheric transfer chamber 8 which is in an atmospheric environment by support arm 17 of transfer apparatus 16, and is received in the FOUP F. Then, the wafer W being cooled at upper cooling plate 33 is continuously cooled regardless of the carry-out operation of the first wafer W, and is received at the FOUP F after a predetermined time is elapsed as the same manner described above.

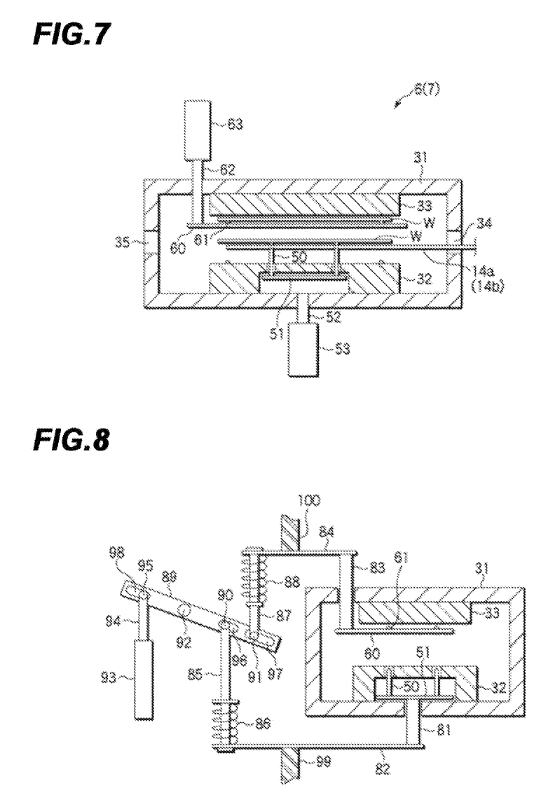

As another exemplary embodiment, as shown in FIG. 7, a wafer W to be cooled by lower cooling plate 32 may be carried into container 31, while another wafer W is being cooled at upper cooling plate 33. Then, the wafer W is received by wafer elevating pin 50 elevated to the transfer position, while another wafer W is supported by support arm 60 at the cooling position adjacent to upper cooling plate 33. Subsequently, the first gate valve G1 is closed, and the pressure in container 31 is adjusted by introducing the purge gas. The wafer W is then descended to the cooling position along with wafer elevating pin 50, and begins to be cooled by lower cooling plate 32.

According to the exemplary embodiment as described above, there are provided two cooling plates including lower cooling plate 32 and upper cooling plate 33, and the cooling operation of the wafer W can be performed at each cooling plate. As a result, the wafer W can be cooled efficiently and the cooling time of the wafer W at load lock apparatuses 6, 7 can be prevented from limiting the processing speed of the entire system. Therefore, the number of wafer processing is not limited by the cooling time at load lock apparatuses 6, 7, and a high throughput of wafer processing is acquired.

Also, since another wafer W can be transferred to another cooling plate while the wafer W is being cooled at any one of cooling plates, the transfer and cooling operation of the wafers are performed as independent sequences in the two cooling plates, thereby increasing the degree of freedom in the cooling operation.

Also, the present invention is not limited to the exemplary embodiments as described above and may have various modifications. For example, though separate driving mechanisms 53, 63 are used when the wafer W is transferred to lower cooling plate 32 and upper cooling plate 33 in the above embodiments, both of the cooling plates may be driven with a single driving mechanism. By this, the structure of the driving system may be simplified. For example, a single two-position air cylinder may be used as a driving mechanism, and the constitution in that case may be formed as illustrated in FIG. 8.

That is to say, a rod 81 is mounted extending downwardly at the center part of the bottom surface of support plate 51 that supports wafer elevating pin 50, and an arm 82 is mounted extending horizontally to the outside of container 31 at the lower end of rod 81. Meanwhile, a rod 83 extending upwardly is mounted on the upper surface of the edge portion of wafer support arm 60, and an arm 84 extending horizontally to the outside of container 31 as the same way as arm 82, is mounted on the upper end of rod 83. And a vertical rod 85 is inserted upwardly at the end of arm 82, and vertical rod 85 is biased upwardly by a spring 86. Also, a vertical rod 87 is inserted downwardly at the end of arm 84, and vertical rod 87 is biased downwardly by a spring 88. Vertical rods 85, 87 are pivotally supported on a bar 89 by pins 90, 91. Bar 89 is adapted to fluctuate vertically along the center of an axis 92 provided in the middle thereof, and vertical rods 85, 87 are supported pivotally at its one side adjacent to each other. A piston 94 of a two-position cylinder 93 is supported pivotally by a pin 95 at the other side. Pins 90, 91, 95 are inserted into long holes 96, 97, 98 formed at bar 89, and forms a link mechanism And vertical rods 85, 87 are moved up and down by piston 94 of two-position cylinder 93 being moved up and down, and wafer elevating pin 50 is also moved up and down via arm 82, rod 81 and support plate 51. And wafer support arm 60 is moved up and down via arm 84 and rod 83. A stopper 99 is provided at the lower portion of arm 82 so as to prevent wafer elevating pin 50 from moving downward beyond a predetermined move-down position, and a stopper 100 is provided at the upper portion of arm 84 so as to prevent wafer support arm 60 supporting the wafer W from moving upward beyond the cooling position adjacent to upper cooling plate 33.

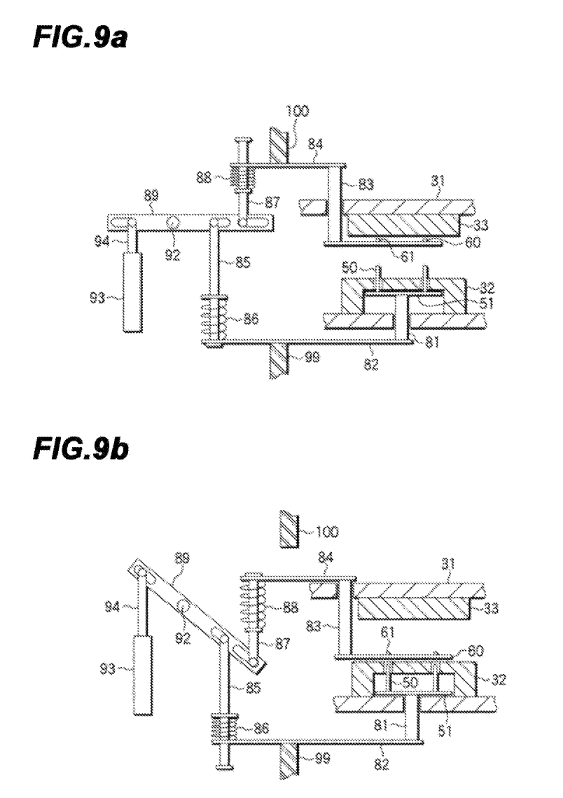

In the load lock apparatus as described above, when two-position cylinder 93 is in a neutral state, wafer elevating pin 50 is in a predetermined descending position, and wafer support arm 60 is in an ascending position, as shown in FIG. 8. If two-position cylinder 93 takes the descending first position from the above state, as shown in FIG. 9a, vertical rod 85 moves up and, along with this, wafer elevating pin 50 moves up to the transfer position via arm 82, rod 81 and support plate 51, thereby transferring the wafer W. Then, wafer support arm 60 stays on the position shown in FIG. 8, because arm 84 is prevented from elevating by stopper 100, although vertical rod 87 is also elevated. Meanwhile, if two-position cylinder 93 takes the ascending second position as shown in FIG. 9b, vertical rod 87 moves down and, along with this, wafer support arm 60 moves down to the transfer position via arm 84 and rod 83, thereby transferring the wafer W. Then, wafer elevating pin 50 stays on the position shown in FIG. 8, because arm 82 is prevented from descending by stopper 99, although vertical rod 85 also moves down.

Therefore, at first, by changing from the state shown in FIG. 8 to the state shown in FIG. 9a, the wafer W is received and carried into wafer elevating pin 50, and then, the wafer W can be cooled only at lower cooling plate 32 by changing into the state shown in FIG. 8 again. The wafer W is then received and carried into wafer support pin 61 of wafer support arm 60 by changing into the state shown in FIG. 9b. The wafer W is then can be cooled at both lower cooling plate 32 and upper cooling plate 33 by changing into the state shown in FIG. 8 again.

Also, although in the above embodiment, the wafer is cooled at a position adjacent to lower cooling plate 32 and upper cooling plate 33, the wafer may be cooled by contacting lower cooling plate 32 and upper cooling plate 33.

Also, although, in the above embodiment, the illustrated multi-chamber type vacuum processing system is provided with four vacuum processing units and two load lock apparatuses, the present invention is not limited to the above numbers. Also, the load lock apparatus of the present invention is not limited to the multi-chamber type vacuum processing apparatus as described above, and is also applicable to a system having one vacuum processing unit. Also, the treated-body is not limited to semiconductor wafers, and is also applicable to other objects such as glass substrate for FPD.

What is claimed is:

1. A load lock apparatus for transferring a substrate from an atmospheric environment to a vacuum chamber maintained in a vacuum state, and for transferring a high-temperature substrate from the vacuum chamber to the atmospheric environment, the load lock apparatus comprising:
a container configured to change pressure between an atmospheric pressure and a pressure corresponding to the vacuum chamber;
a pressure adjusting mechanism configured to adjust the pressure in the container to the pressure corresponding to the vacuum chamber when the container is in communication with the vacuum chamber, and to adjust the pressure in the container to the atmospheric pressure when the container is in communication with a space of the atmospheric environment;
a first cooling member and a second cooling member provided opposed to each other inside the container and configured to cool the substrate at a place adjacent to the substrate or in touch with the substrate;
a first transfer mechanism configured to receive the substrate transferred inside the container and to transfer the substrate to a position adjacent to the first cooling member or in touch with the first cooling member; and
a second transfer mechanism configured to receive the substrate transferred inside the container and to transfer the substrate to a position adjacent to the second cooling member or in touch with the second cooling member.

2. The load lock apparatus according to claim 1, wherein the first transfer mechanism transfers the substrate between a transfer position where the substrate is delivered to and from an outside transfer arm, and a cooling position adjacent to the first cooling member or in touch with the first cooling member, and
the second transfer mechanism transfers the substrate between a transfer position where the substrate is delivered to and from an outside transfer arm, and a cooling position adjacent to the second cooling member or in touch with the second cooling member.

3. The load lock apparatus according to claim 2, further comprising a control unit configured to control the first and the second transfer mechanisms so that while cooling the substrate by making the substrate to touch or to move adjacent to any one of the first and the second cooling members by any one of the first and the second transfer mechanisms, the substrate is transferred to the other one of the first and the second cooling members by the other one of the first and the second transfer mechanisms.

4. The load lock apparatus according to claim 1, wherein each of the first and the second transfer mechanisms includes a substrate supporting member to support the substrate, and a driving mechanism to drive the substrate supporting member.

5. The load lock apparatus according to claim 4, wherein each of the first and the second transfer mechanism is provided with an independent drive mechanism.

6. The load lock apparatus according to claim 4, wherein the first and the second transfer mechanism include a common drive mechanism.

7. The load lock apparatus according to claim 1, wherein the first cooling member is provided at a lower part of the container to cool the substrate from a down side, and
the second cooling member is provided at an upper part of the container to cool the substrate from an upside.

8. The load lock apparatus according to claim 7, wherein the first transfer mechanism includes a support pin provided on the first cooling member to be able to protrude and retract, and a driving mechanism configured to elevate the support pin, and
the second transfer mechanism includes a substrate support member configured to support the substrate and provided in contact with or detachable from the second cooling member, and a driving mechanism to elevate the substrate support member.

9. The load lock apparatus according to claim 8, wherein each of the first and the second transfer mechanisms is provided with an independent driving mechanism.

10. The load lock apparatus according to claim 8, wherein the first and the second transfer mechanisms include a common drive mechanism.

11. A substrate cooling method for a load lock apparatus for transferring a substrate from an atmospheric environment to a vacuum chamber maintained in a vacuum state, and for transferring a high-temperature substrate from the vacuum chamber to the atmospheric environment, where the load lock apparatus comprising:
a container configured to change pressure between an atmospheric pressure and a pressure corresponding to the vacuum chamber;
a pressure adjusting mechanism configured to adjust the pressure in the container to the pressure corresponding to the vacuum chamber when the container is in communication with the vacuum chamber, and to adjust the pressure in the container to the atmospheric pressure when the container is in communication with a space of the atmospheric environment;
a first cooling member and a second cooling member provided opposed to each other inside the container and configured to cool the substrate at a place adjacent to the substrate or in touch with the substrate;
a first transfer mechanism configured to receive the substrate transferred inside the container and to transfer the substrate to a position adjacent to the first cooling member or in touch with the first cooling member; and
a second transfer mechanism configured to receive the substrate transferred inside the container and to transfer the substrate to a position adjacent to the second cooling member or in touch with the second cooling member,
and the substrate cooling method comprising:
cooling the substrate by moving the substrate into a place adjacent to or to touch any one of the first and the second cooling members with any one of the first and the second transfer mechanisms; and
transferring the substrate to the other one of the first and the second cooling members by the other one of the first and the second transfer mechanisms while cooling the substrate.
